(19) United States
(12) Patent Application Publication
(10) Pub. No.: US 2019/0378838 A1
(43) Pub. Date: Dec. 12, 2019

(54) SEMICONDUCTOR DEVICE AND METHOD OF MANUFACTURING THE SAME

(71) Applicant: Samsung Electronics Co., Ltd., Suwon-si (KR)

(72) Inventors: Yong-ho Jeon, Hwaseong-si (KR); Jong-chul Park, Seongnam-si (KR); Sung-woo Myung, Seoul (KR); Jung-hyun Kim, Hwaseong-si (KR)

(73) Assignee: Samsung Electronics Co., Ltd., Suwon-si (KR)

(21) Appl. No.: 16/218,714

(22) Filed: Dec. 13, 2018

(30) Foreign Application Priority Data
Jun. 11, 2018 (KR) 10-2018-0067062

(51) Int. Cl. H01L 27/088; H01L 29/08; H01L 29/66; H01L 29/78; H01L 21/308; H01L 21/8234; H01L 29/423; H01L 29/51

(52) U.S. Cl. CPC H01L 27/0886; H01L 29/0847; H01L 29/66545; H01L 29/66795; H01L 29/7851; H01L 21/3086; H01L 29/51; H01L 21/823481; H01L 21/823468; H01L 21/823462; H01L 21/823437; H01L 29/42356; H01L 21/823431

(57) ABSTRACT

Provided is a semiconductor device including: a plurality of active regions extending on a substrate in a first direction; first and second gate structures spaced apart from each other in the first direction and extending on the substrate in a second direction crossing the plurality of active regions; an interlayer insulating layer covering around the first and second gate structures; and an inter-gate cutting layer traversing the first and second gate structures and the interlayer insulating layer in the first direction, the inter-gate cutting layer including an insulating material, wherein the first and second gate structures are cut by the inter-gate cutting layer, wherein a level of a bottom surface of the inter-gate cutting layer at a region cutting the first and second gate structures is lower than a level of a bottom surface of the inter-gate cutting layer in the interlayer insulating layer.

### CROSS-REFERENCE TO RELATED APPLICATION

This application claims the benefit of Korean Patent Application No. 10-2018-0067062, filed on Jun. 11, 2018, in the Korean Intellectual Property Office, the disclosure of which is incorporated herein in its entirety by reference.

### BACKGROUND

The inventive concepts relate to a semiconductor device and a method of manufacturing the same, and more particularly, to a semiconductor device including a field-effect transistor, and a method of manufacturing the semiconductor device.

According to a decrease in a feature size of a field-effect transistor, a length of a gate and/or a length of a channel provided below the gate have been decreased. In this regard, various attempts have been made to improve a structure and/or manufacturing method of a semiconductor device, so as to increase operation stability and/or reliability of transistors that are important factors for determining the performance of integrated circuits.

### SUMMARY

The inventive concepts provide a semiconductor device including a gate structure formed by using a replacement metal gate (RMG) process, wherein issues occurring in a cut region of the gate structure may be solved.

The inventive concepts provide a method of manufacturing a semiconductor device including a gate structure formed by using an RMG process, wherein issues occurring in a cut region of the gate structure may be solved.

According to an aspect of the inventive concepts, there is provided a semiconductor device including: a plurality of active regions on a substrate extending in a first direction; first and second gate structures spaced apart from each other in the first direction and extending on the substrate in a second direction crossing the plurality of active regions; an interlayer insulating layer around the first and second gate structures; and an inter-gate cutting layer traversing the first and second gate structures and the interlayer insulating layer in the first direction, the inter-gate cutting layer including an insulating material, wherein the first and second gate structures are separated by the inter-gate cutting layer, wherein a level of a bottom surface of the inter-gate cutting layer at a region cutting the first and second gate structures is lower than a level of a bottom surface of the inter-gate cutting layer in the interlayer insulating layer.

According to another aspect of the inventive concept, there is provided a semiconductor device including: a plurality of active fins on a substrate extending in a first direction; first and second gate structures spaced apart from each other in the first direction and extending on the substrate in a second direction crossing the plurality of active fins; a source/drain region in a region of the plurality of active fins, which is not covered by the first and second gate structures; an interlayer insulating layer covering the source/drain region around the first and second gate structures; and an inter-gate cutting layer traversing the first and second gate structures and the interlayer insulating layer in the first direction, wherein the first and second gate structures each include a spacer including a multilayer material layer on two side surfaces thereof, wherein the number of material layers of the spacer provided at the inter-gate cutting layer is less than the number of material layers of the spacer provided at the first and second gate structures, wherein a level of a bottom surface of the inter-gate cutting layer at a region cutting the first and second gate structures is lower than a level of a bottom surface of the inter-gate cutting layer in the interlayer insulating layer.

According to another aspect of the inventive concepts, there is provided a method of manufacturing a semiconductor device, the method including: forming a plurality of active regions extending on a substrate in a first direction, and a device isolating layer defining the plurality of active regions; forming a dummy gate structure including a dummy gate pattern and a spacer, and extending on the device isolating layer in a second direction while crossing the plurality of active regions; forming a source/drain region at a region of the plurality of active regions, which is exposed at two sides of the dummy gate structure; forming an interlayer insulating layer covering the device isolating layer and the source/drain region around the dummy gate structure; forming an empty space extending in the second direction between the spacer by removing the dummy gate pattern; forming a gate structure including a gate electrode and the spacer by filling the empty space with a metal material to form the gate electrode; removing a part of the spacer; and cutting the gate electrode by removing a region where a side surface of the gate electrode is exposed when the spacer is removed within the gate electrode.

### BRIEF DESCRIPTION OF THE DRAWINGS

Embodiments of the inventive concepts will be more clearly understood from the following detailed description taken in conjunction with the accompanying drawings in which:

FIG. 1 is a perspective view of a semiconductor device according to an embodiment of the inventive concepts;

FIG. 2A is a plan view of a semiconductor device according to an embodiment of the inventive concepts;

FIG. 2B is a cross-sectional view taken along lines A-A′, B-B′, and C-C′ of FIG. 2A;

FIG. 2C is a cross-sectional view taken along lines D-D′ and E-E′ of FIG. 2A;

FIGS. 3A, 4A, 5A, 6A, 7A, and 8A are plan views of a semiconductor device in an order of processes of a method of manufacturing the semiconductor device, according to an embodiment of the inventive concepts;

FIGS. 3B, 4B, 5B, 6B, 7B, and 8B are cross-sectional views respectively taken along lines A-A′, B-B′, and C-C′ of FIGS. 3A, 4A, 5A, 6A, 7A, and 8A;

FIGS. 3C, 4C, 5C, 6C, 7C, and 8C are cross-sectional views taken along lines D-D′ and E-E′ respectively of FIGS. 3A, 4A, 5A, 6A, 7A, and 8A;

FIG. 9A is a plan view of a semiconductor device according to another embodiment of the inventive concepts;

FIG. 9B is a cross-sectional view taken along lines A-A′, B-B′, and C-C′ of FIG. 9A;

FIG. 9C is a cross-sectional view taken along lines D-D′ and E-E′ of FIG. 9A;

FIGS. 10 and 11 are cross-sectional views of a semiconductor device in an order of processes of a part of a method of manufacturing the semiconductor device, according to another embodiment of the inventive concepts;

FIG. 12A is a plan view of a semiconductor device according to another embodiment of the inventive concepts;

FIG. 12B is a cross-sectional view taken along lines A-A′, B-B′, and C-C′ of FIG. 12A;

FIG. 12C is a cross-sectional view taken along lines D-D′ and E-E′ of FIG. 12A;

FIGS. 13 through 15 are cross-sectional views of a semiconductor device in an order of processes of a part of a method of manufacturing the semiconductor device, according to another embodiment of the inventive concepts; and

FIG. 16 is a diagram of a system including a semiconductor device, according to an embodiment of the inventive concepts.

### DETAILED DESCRIPTION OF EMBODIMENTS

Hereinafter, one or more embodiments of the inventive concepts are described in detail with reference to accompanying drawings.

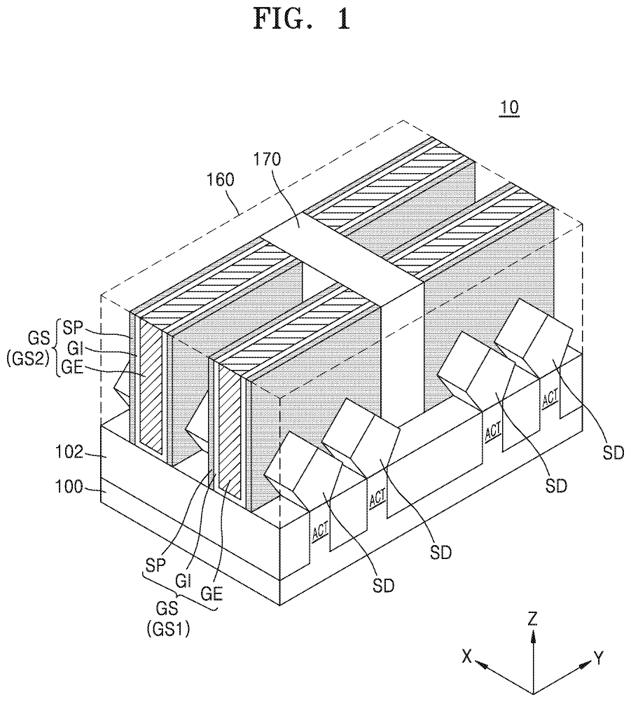

FIG. 1 is a perspective view of a semiconductor device 10 according to an embodiment of the inventive concepts.

Referring to FIG. 1, the semiconductor device 10 includes a plurality of active regions ACT extending on a substrate 100 in a first direction X, a plurality of gate structures GS spaced apart from each other in the first direction X and extending in a second direction Y crossing the plurality of active regions ACT, a source/drain region SD provided in a region not covered by the plurality of gate structures GS, an interlayer insulating layer 160 around the plurality of gate structures GS, and/or an inter-gate cutting layer 170 traversing the plurality of gate structures GS and the interlayer insulating layer 160 in the first direction X.

According to a decrease in a feature size of a semiconductor device, semiconductor devices are being gradually highly integrated and/or miniaturized. Accordingly, in order to increase an effect of using a side surface of an active fin forming a fin field-effect transistor (FinFET) as a channel, a height of a gate structure is gradually increasing. As such, due to the increase in the height of the gate structure, process difficulty with respect to forming the gate structure required for the semiconductor device by using a replacement metal gate (RMG) process is gradually increasing.

Unlike the technical ideas of the inventive concepts, when a process of cutting a dummy gate structure is performed first and then a process of replacing the cut dummy gate structure with a metal gate structure required in a final structure is used to form a gate structure required in a semiconductor device by using an RMG process, a process window with respect to the process of cutting the dummy gate structure may decrease.

On the other hand, according to a method of manufacturing the semiconductor device, according to the technical ideas of the inventive concepts, a dummy gate pattern may be replaced by a preliminary gate electrode including a metal material by using an RMG process, and the preliminary gate electrode may be patterned to be separated into a pair of gate electrodes GE spaced apart from each other and facing each other in the second direction Y. Accordingly, issues that may occur when a cut region is formed in the dummy gate pattern may be solved.

Unlike the technical ideas of the inventive concepts, when processes of forming a gate structure including a metal gate electrode first and then cutting the gate structure are used with respect to forming of a gate structure required in a semiconductor device by using an RMG process, it may be difficult to completely remove residue or etching by-products of the metal gate electrode according to an etching profile of the metal gate electrode. An over-etching process is required to completely remove the residue or etching by-products of the metal gate electrode, but in this case, a part of a source/drain region adjacent to the metal gate electrode may be etched, and thus characteristics of the semiconductor device may deteriorate.

On the other hand, according to the method of manufacturing the semiconductor device, according to the technical ideas of the inventive concepts, by removing preliminary spaces at two sides of a preliminary gate electrode before the preliminary gate electrode during a process of cutting a gate structure, a sufficient space for etching a metal material around the preliminary gate electrode may be obtained. Thus, the pair of gate electrodes GE may be reduced or prevented from being electrically short-circuited due to residue or etching by-products of the preliminary gate electrode, the residue or etching by-products being generated while the preliminary gate electrode is removed.

In addition, a cut region may be formed in the source/drain region SD by using an etch condition having a partial etch selectivity with respect to the interlayer insulating layer 160 such that only a top portion of the interlayer insulating layer 160 is removed and a bottom portion of the interlayer insulating layer 160 is left. Accordingly, by performing the process of forming the cut region, a defect generated when a part of the source/drain region SD is etched may be reduced or prevented.

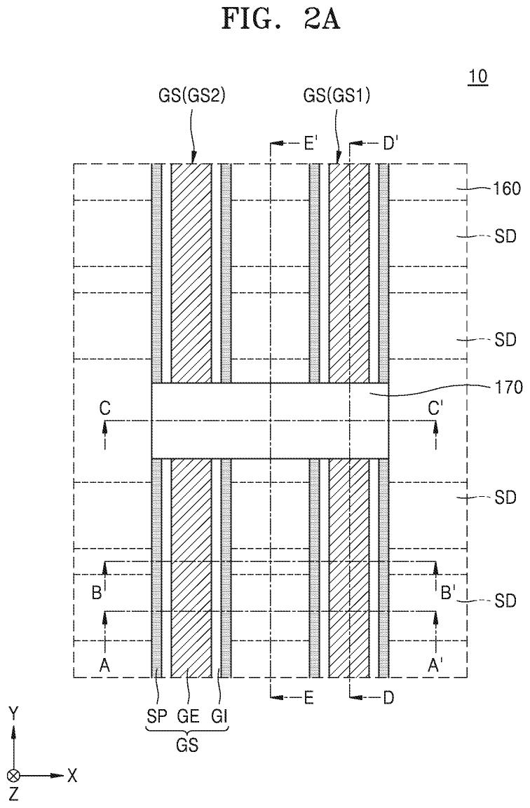

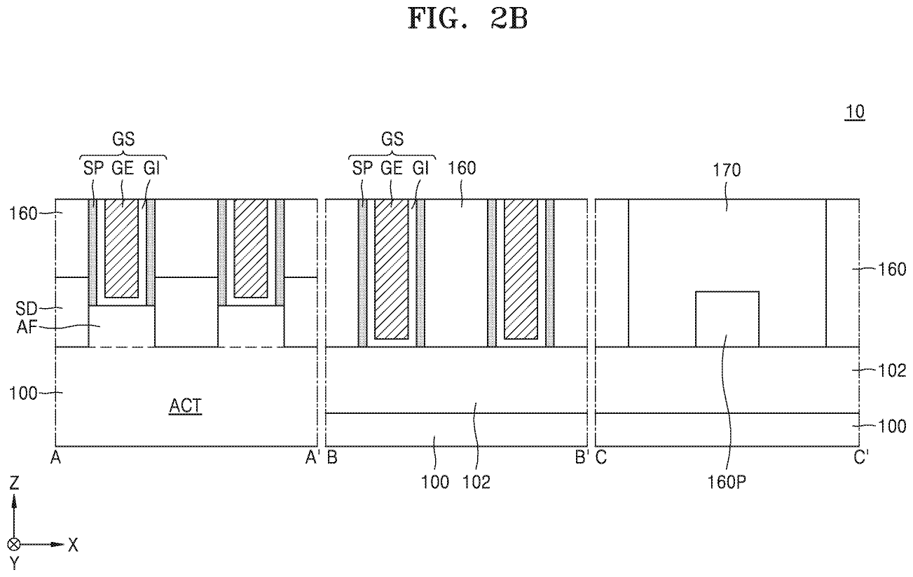

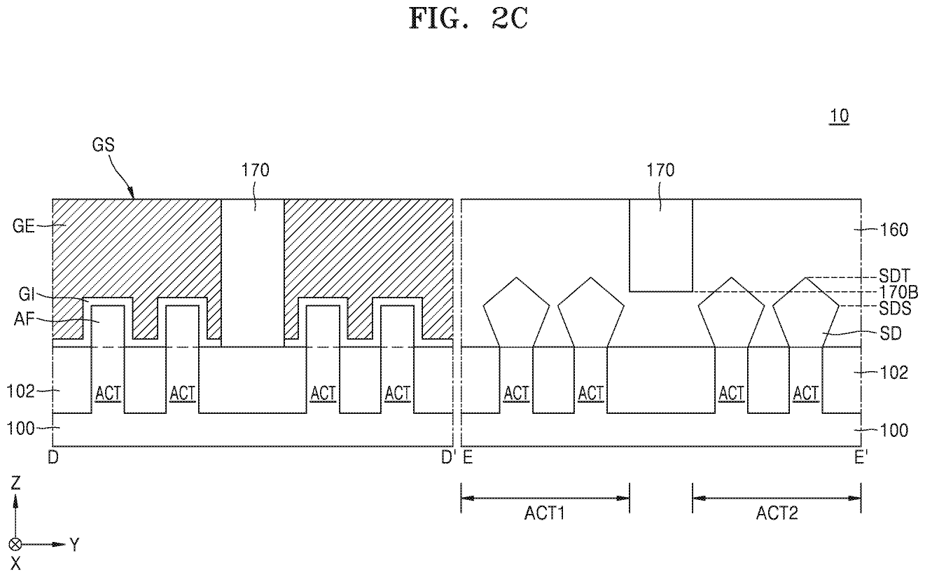

FIG. 2A is a plan view of the semiconductor device 10 according to an embodiment of the inventive concepts, FIG. 2B is a cross-sectional view taken along lines A-A′, B-B′, and C-C′ of FIG. 2A, and FIG. 2C is a cross-sectional view taken along lines D-D′ and E-E′ of FIG. 2A.

Referring to FIGS. 2A through 2C, the semiconductor device 10 includes the inter-gate cutting layer 170 traversing and cutting the plurality of gate structures GS in the first direction X.

The active region ACT may be provided on the substrate 100. The substrate 100 may be a semiconductor substrate. According to some embodiments, the substrate 100 may include a semiconductor, such as a silicon (Si) or a germanium (Ge), or may include a compound semiconductor, such as SiGe, silicon carbide (SiC), gallium arsenide (GaAs), indium arsenide (InAs), or indium phosphide (InP). According to another embodiment, the substrate 100 may have a silicon-on-insulator (SoI) structure, and the substrate 100 may include a conductive region, for example, an impurity-doped well or an impurity-doped structure.

The active region ACT may extend in the first direction X parallel to a top surface of the substrate 100. There may be a plurality of active regions ACT that are parallel to the top surface of the substrate 100 and spaced apart from each other in the second direction Y crossing the first direction X. Also, the active region ACT may protrude from the substrate 100 in a third direction Z perpendicular to the top surface of the substrate 100.

A device isolating layer 102 defining the active region ACT may be provided at two sides of the active region ACT. The device isolating layers 102 may extend on the substrate 100 in the first direction X and may be spaced apart from each other in the second direction Y across the active region ACT. The device isolating layer 102 may include at least one of silicon oxide, silicon nitride, and silicon oxynitride.

According to some embodiments, the device isolating layer 102 may expose a top region of the active region ACT. In other words, the active region ACT may include an active fin AF that is the top region exposed by the device isolating layer 102. According to other embodiments, a level of a top surface of the active region ACT may be substantially the same as a level of a top surface of the device isolating layer 102.

The active region ACT may include the plurality of active fins AF protruding from the substrate 100 and be divided into a first active region ACT1 including at least one active fin AF selected from the plurality of active fins AF and a second active region ACT2 separated from the first active region ACT1 and including another at least one active fin AF.

The gate electrode GE traversing the active region ACT and the device isolating layer 102 may be provided on the substrate 100. The gate electrode GE may cover the active fin AF and may extend in the second direction Y to cover a top surface of the device isolating layer 102. There may be a pair of gate electrodes GE extending in the second direction Y while facing each other across the inter-gate cutting layer 170.

A gate dielectric layer GI may be provided between the gate electrode GE and the active fin AF. The gate dielectric layer GI may extend between the gate electrode GE and the device isolating layer 102 and may extend between the gate electrode GE and a spacer SP. As shown in FIG. 2B, a level of an uppermost surface of the gate dielectric layer GI may be substantially the same as a level of a top surface of the gate electrode GE. The spacer SP may be spaced apart from the gate electrode GE across the gate dielectric layer GI.

In a plan view, the inter-gate cutting layer 170 may extend in the first direction X to contact each of a cut side surface of the gate electrode GE, a cut side surface of the gate dielectric layer GI, and a cut side surface of the spacer SP.

The gate electrode GE, the gate dielectric layer GI, and/or the spacer SP may be defined as the gate structure GS. The pair of gate structures GS may face each other in the second direction Y and be spaced apart from each other by the inter-gate cutting layer 170. Each of the pair of gate structures GS may traverse the respective active region ACT. The pair of gate structures GS may include a pair of gate electrodes GE spaced apart from each other in the second direction Y. The pair of gate structures GS may traverse the first active region ACT1 and the second active region ACT2, respectively.

The inter-gate cutting layer 170 may be provided on the device isolating layer 102 and an interlayer insulating pattern 160P. The inter-gate cutting layer 170 may include a single insulating material or a plurality of insulating materials. According to some embodiments, the inter-gate cutting layer 170 may include silicon oxide, silicon nitride, silicon oxynitride, or a combination thereof.

Also, another pair of gate structures GS may face each other in the second direction Y and may be spaced apart from each other by the inter-gate cutting layer 170. Despite the gate structures GS having the same structure, the pair of gate structures GS may be referred to as first gate structures GS1 and the other pair of gate structures GS may be referred to as second gate structures GS2 for convenience of description. The second gate structures GS2 may be spaced apart from the first gate structures GS1 in the first direction X. The second gate structures GS2 may traverse the first active region ACT1 and the second active region ACT2, respectively.

The inter-gate cutting layer 170 is provided between the first and second active regions ACT1 and ACT2, a bottom shape of the inter-gate cutting layer 170 may be uneven, and a top shape of the inter-gate cutting layer 170 may be relatively flat. The inter-gate cutting layer 170 may extend in the third direction Z to fill a cut region between the first gate structures GS1. Also, the inter-gate cutting layer 170 may extend in the third direction Z to fill a cut region between the second gate structures GS2.

In detail, the first and second gate structures GS1 and GS2 are cut by the inter-gate cutting layer 170, and a level of a bottom surface (a surface contacting the device isolating layer 102) of the inter-gate cutting layer 170 at a region cutting the first and second gate structures GS1 and GS2 may be lower than a level of a bottom surface 170B (a surface contacting the interlayer insulating pattern 160P) of the inter-gate cutting layer 170 in the interlayer insulating layer 160. In other words, the level of the bottom surface 170B of the inter-gate cutting layer 170 in the interlayer insulating layer 160 may be substantially the same as a level of a top surface of the interlayer insulating pattern 160P.

The source/drain region SD may be provided on each of the active regions ACT at two sides of the gate structures GS. The source/drain regions SD may be spaced apart from each other across the gate structure GS. A level of a bottom surface of the source/drain region SD may be lower than a level of a top surface of the active fin AF. The source/drain region SD may be a selective epitaxial growth layer formed by using the active region ACT as a seed.

As shown in FIG. 2C, the source/drain region SD, e.g., a selective epitaxial growth layer, may have a protruding point SDS at a side surface, in the second direction Y. The level of the bottom surface 170B of the inter-gate cutting layer 170 in the interlayer insulating layer 160 may be lower than a level of an uppermost surface SDT of the source/drain region SD and higher than a level of the protruding point SDS. In other words, the inter-gate cutting layer 170 may reduce or prevent the source/drain region SD from being damaged.

The interlayer insulating layer 160 covering the source/drain region SD around the gate structure GS may be provided on the substrate 100. The interlayer insulating layer 160 may include a single insulating material or a plurality of insulating materials. A level of a top surface of the inter-gate cutting layer 170 may be substantially the same as a level of a top surface of the interlayer insulating layer 160. Also, a level of a top surface of the gate electrode GE may be substantially the same as the level of the top surface of the inter-gate cutting layer 170.

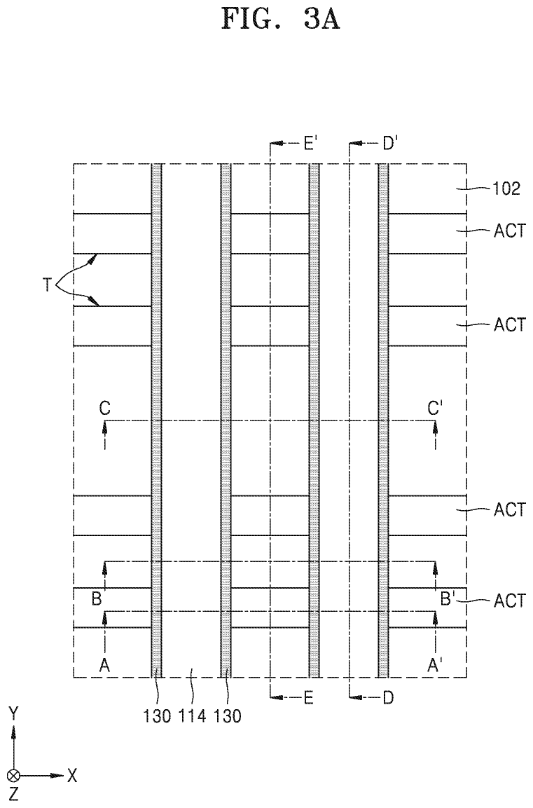

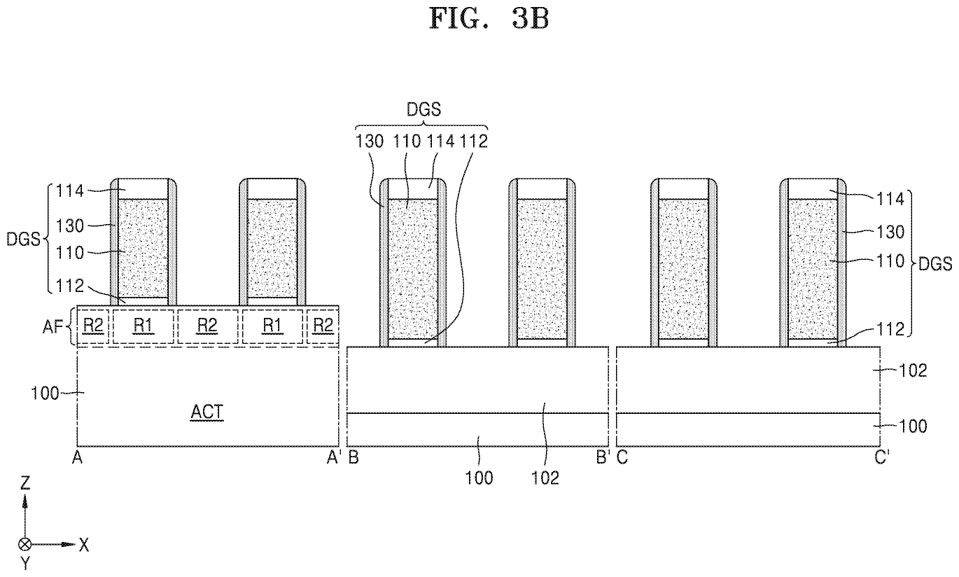

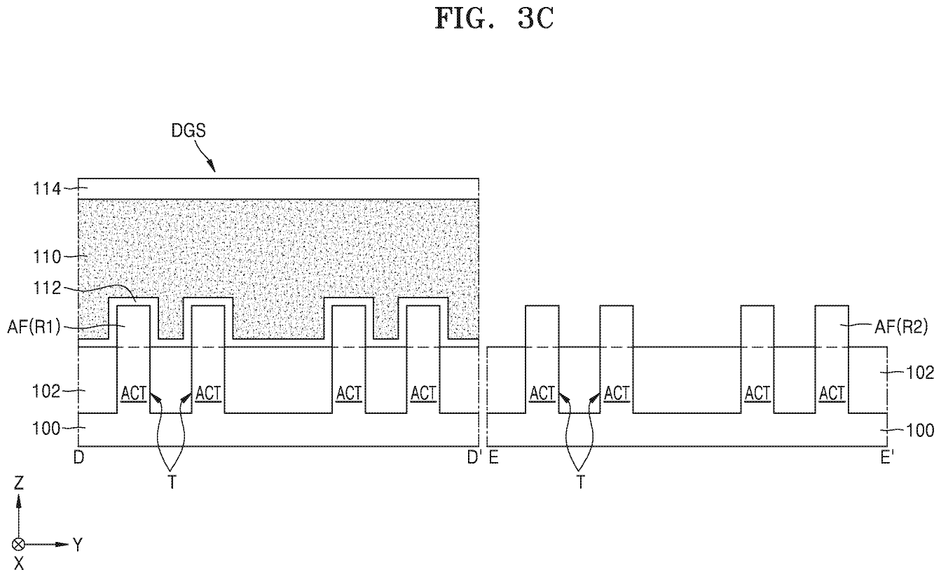

FIGS. 3A, 4A, 5A, 6A, 7A, and 8A are plan views of the semiconductor device 10 in an order of processes of a method of manufacturing the semiconductor device 10, according to an embodiment of the inventive concepts, FIGS. 3B, 4B, 5B, 6B, 7B, and 8B are cross-sectional views respectively taken along lines A-A′, B-B′, and C-C′ of FIGS. 3A, 4A, 5A, 6A, 7A, and 8A, and FIGS. 3C, 4C, 5C, 6C, 7C, and 8C are cross-sectional views respectively taken along lines D-D′ and E-E′ of FIGS. 3A, 4A, 5A, 6A, 7A, and 8A.

Referring to FIGS. 3A through 3C, the active region ACT may be formed on the substrate 100, and the device isolating layer 102 may be formed on two sides of the active region ACT.

A process of forming the active region ACT may include a process of forming a trench T defining the active region ACT by patterning the substrate 100. The trenches T may be in the form of a line extending in the first direction X and may be spaced apart from each other in the second direction Y. The process of forming the trench T may include a process of forming a mask pattern (not shown) defining a region where the active region ACT is to be formed on the substrate 100 and a process of etching the substrate 100 by using the mask pattern as an etch mask.

The device isolating layer 102 may be formed to fill the trench T. A process of forming the device isolating layer 102 may include a process of forming an insulating layer filling the trench T on the substrate 100 and a process of flattening the insulating layer so that the mask pattern is exposed. After the process of flattening the insulating layer, the top of the device isolating layer 102 may be recessed such that the top of the active region ACT is exposed. The top of the active region ACT exposed by the device isolating layer 102 may be defined by the active fin AF.

A process of recessing the top of the device isolating layer 102 may be performed by using an etch condition having etch selectivity with respect to the active region ACT. The top of the device isolating layer 102 may be recessed, and the mask pattern may be removed.

A dummy gate pattern 110 traversing the active region ACT and the device isolating layer 102 may be formed on the substrate 100. The dummy gate pattern 110 may extend in the second direction Y. The dummy gate pattern 110 may cover the active fin AF and extend on the top surface of the device isolating layer 102.

When there are a plurality of the active regions ACT, the plurality of active regions ACT may extend in the first direction X and be spaced part from each other in the second direction Y. In this case, the dummy gate pattern 110 may extend in the second direction Y to traverse the plurality of active regions ACT.

An etch stop pattern 112 may be provided between the dummy gate pattern 110 and the active region ACT, and provided between the dummy gate pattern 110 and the device isolating layer 102. Processes of forming the dummy gate pattern 110 and the etch stop pattern 112 may include a process of sequentially forming an etch stop layer and a dummy gate layer covering the active region ACT and the device isolating layer 102 on the substrate 100, a process of forming a dummy mask pattern 114 defining a region where the dummy gate pattern 110 is to be formed on the dummy gate layer, and a process of sequentially patterning the dummy gate layer and the etch stop layer by using the dummy mask pattern 114 as an etch mask. The dummy gate layer may include a material having etch selectivity with respect to the etch stop layer. The etch stop layer may include, for example, silicon oxide, and the dummy gate layer may include, for example, polysilicon.

After the dummy gate pattern 110 is formed, the etch stop layer on two sides of the dummy gate pattern 110 is removed to form the etch stop pattern 112 below the dummy gate pattern 110.

The dummy gate pattern 110, the etch stop pattern 112, and the dummy mask pattern 114 may each include a preliminary spacer 130 extending from a respective side surface thereof. The preliminary spacer 130 may include, for example, silicon nitride. A process of forming the preliminary spacer 130 may include a process of forming a spacer layer covering the dummy gate pattern 110, the etch stop pattern 112, and the dummy mask pattern 114, and a process of etching the spacer layer.

The dummy gate pattern 110, the etch stop pattern 112, the dummy mask pattern 114, and the preliminary spacer 130 may be defined as a dummy gate structure DGS. When the dummy gate structure DGS is formed to traverse the active region ACT, a first region R1 and a second region R2 may be defined in the active fin AF. The first region R1 is provided below the dummy gate structure DGS and may be a partial region of the active fin AF overlapping the dummy gate structure DGS in a plan view. The second region R2 is provided on two sides of the dummy gate structure DGS and may be another partial region of the active fin AF horizontally separated by the first region R1.

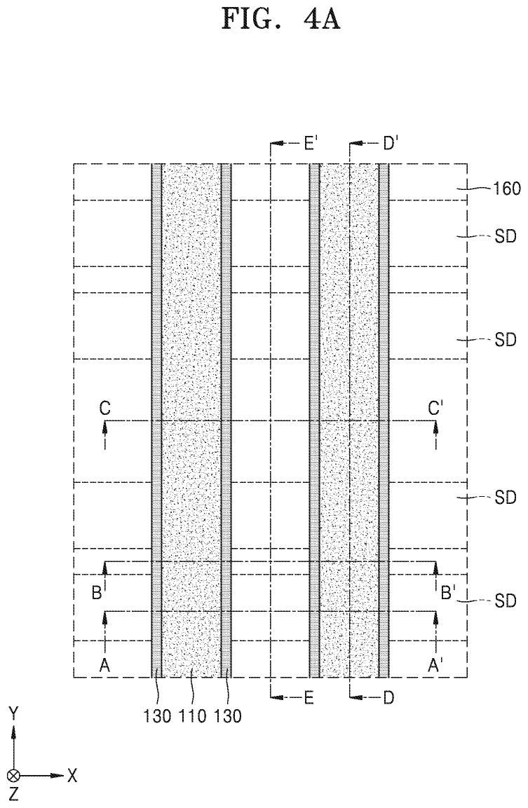

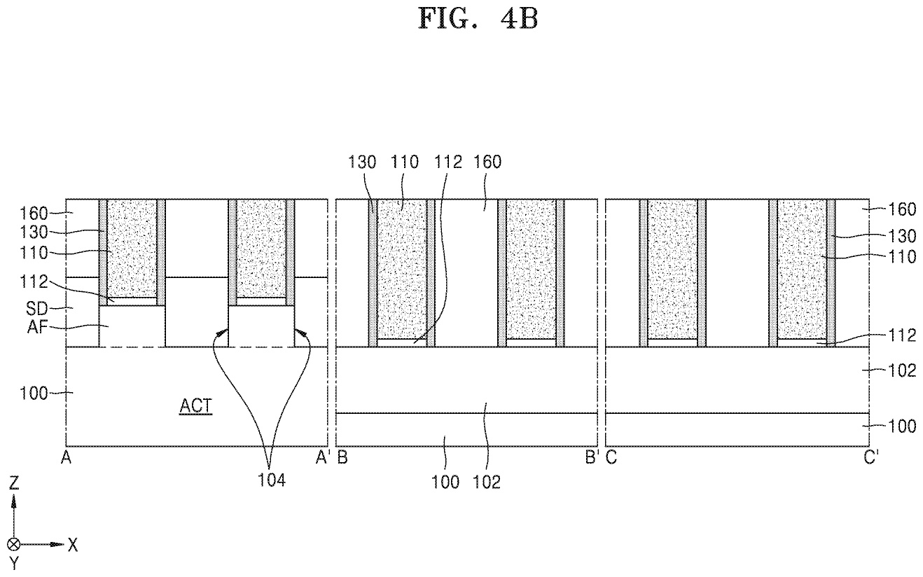

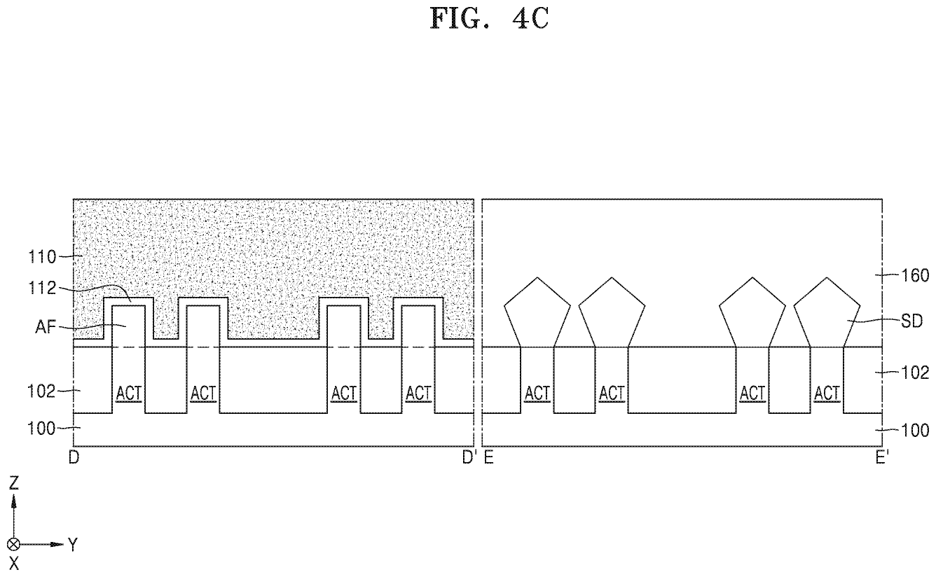

Referring to FIGS. 4A through 4C, a recess region 104 may be formed in the active region ACT when the second region R2 of the active fin AF is removed. A process of removing the second region R2 of the active fin AF may be performed, for example, via a dry etch process.

The source/drain region SD may be formed on the active region ACT on two sides of the dummy gate structure DGS. The source/drain region SD may be formed to fill the recess region 104. The source/drain region SD may be formed by performing a selective epitaxial growth process by using a surface of the active region ACT, which is exposed by the recess region 104, as a seed. Each source/drain region SD may include at least one of silicon germanium (SiGe), silicon (Si), and silicon carbide (SiC), which are grown by using the surface of the active region ACT as a seed.

The process of forming the source/drain region SD may include the selective epitaxial growth process and simultaneously or after the selective epitaxial growth process, a process of doping the source/drain region SD with an impurity. The process of doping the impurity may be performed to improve electrical characteristics of a transistor including the source/drain region SD. When the transistor is an n-type, the impurity may be, for example, phosphorous (P), and when the transistor is a p-type, the impurity may be, for example, boron (B).

The interlayer insulating layer 160 may be formed on the substrate 100 where the source/drain region SD is formed. A process of forming the interlayer insulating layer 160 may include a process of forming an insulating layer covering the source/drain region SD and the dummy gate structure DGS on the substrate 100 and a process of planarizing the interlayer insulating layer 160 so that the top surface of the dummy gate pattern 110 is exposed. The dummy mask pattern 114 may be removed by the process of planarizing the interlayer insulating layer 160. The interlayer insulating layer 160 may include at least one of silicon oxide, silicon nitride, silicon oxynitride, and a low-dielectric material.

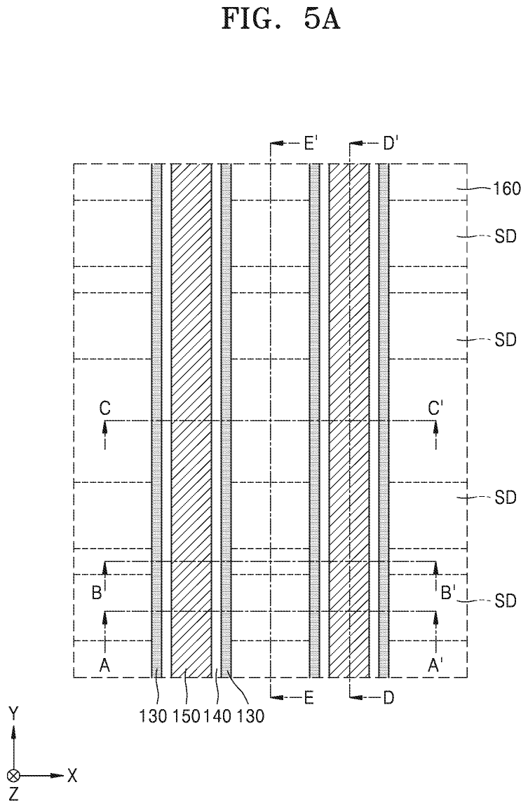

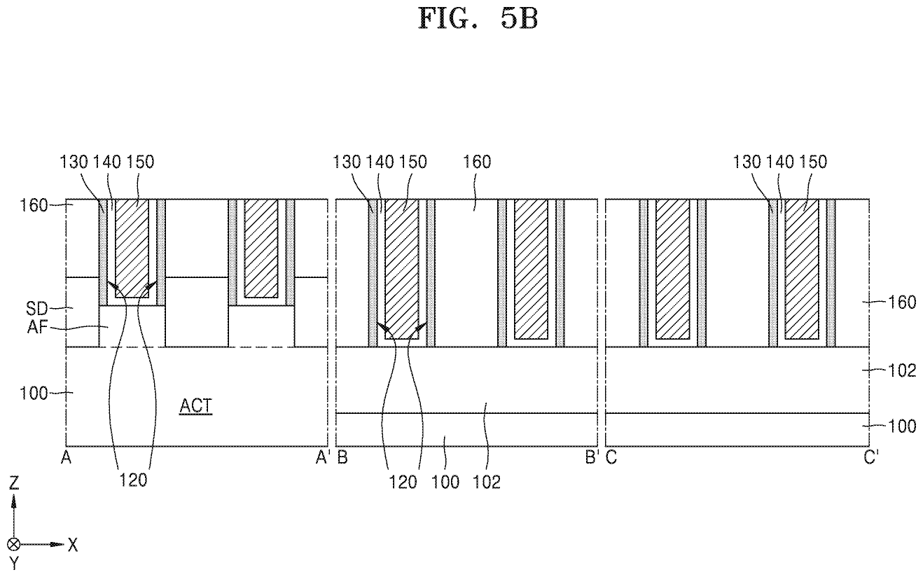

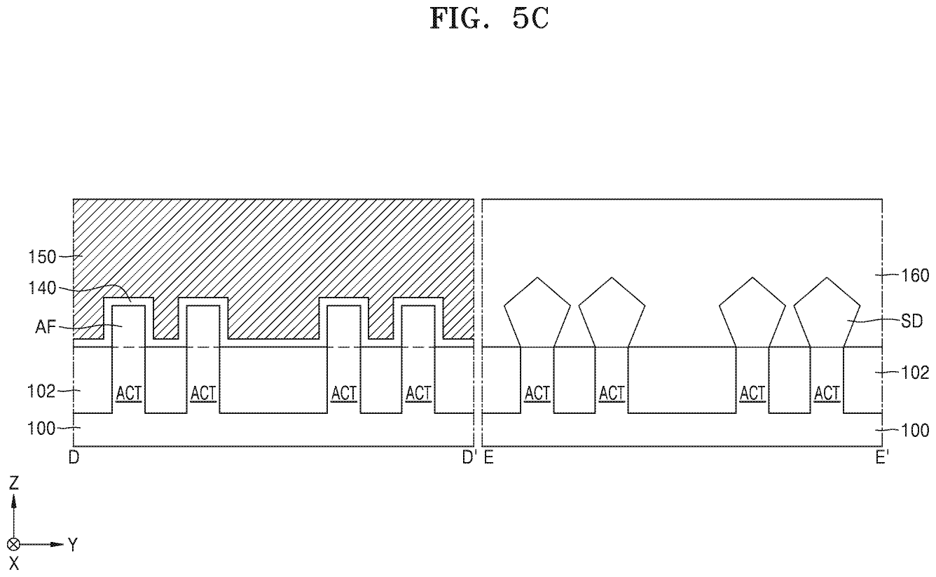

Referring to FIGS. 5A through 5C, a gap region 120 may be formed in the preliminary spacer 130 by removing the dummy gate pattern 110 and the etch stop pattern 112. The gap region 120 may be an empty space defined by the preliminary spacer 130. The gap region 120 may expose the top surface of the active fin AF. A process of forming the gap region 120 may include a process of removing the dummy gate pattern 110 under an etch condition having etch selectivity with respect to the preliminary spacer 130, the interlayer insulating layer 160, and the etch stop pattern 112. In addition, the process of forming the gap region 120 may include a process of exposing the top surface of the active fin AF by removing the etch stop pattern 112.

A preliminary gate dielectric layer 140 and a preliminary gate electrode 150, which fill the gap region 120, may be formed. In detail, the preliminary gate dielectric layer 140 conformally filling a part of the gap region 120. The preliminary gate dielectric layer 140 may be formed to cover the top surface of the active fin AF. The preliminary gate dielectric layer 140 may include a high-dielectric material, for example, at least one of hafnium oxide, hafnium silicate, zirconium oxide, and zirconium silicate.

The preliminary gate dielectric layer 140 may be formed, for example, via an atomic layer deposition process. The preliminary gate electrode 150 filling the remaining part of the gap region 120 may be formed on the preliminary gate dielectric layer 140. The preliminary gate electrode 150 may include a first conductive layer adjacent to the preliminary gate dielectric layer 140 and a second conductive layer adjacent to the first conductive layer and spaced apart from the preliminary gate dielectric layer 140.

The first conductive layer may include at least one conductive metal nitride, and the second conductive layer may include at least one of conductive metal nitrides and metals. The second conductive layer may include a material different from the first conductive layer. The preliminary gate dielectric layer 140 may extend along a bottom surface and a side surface of the preliminary gate electrode 150 to be provided between the preliminary gate electrode 150 and the preliminary spacer 130.

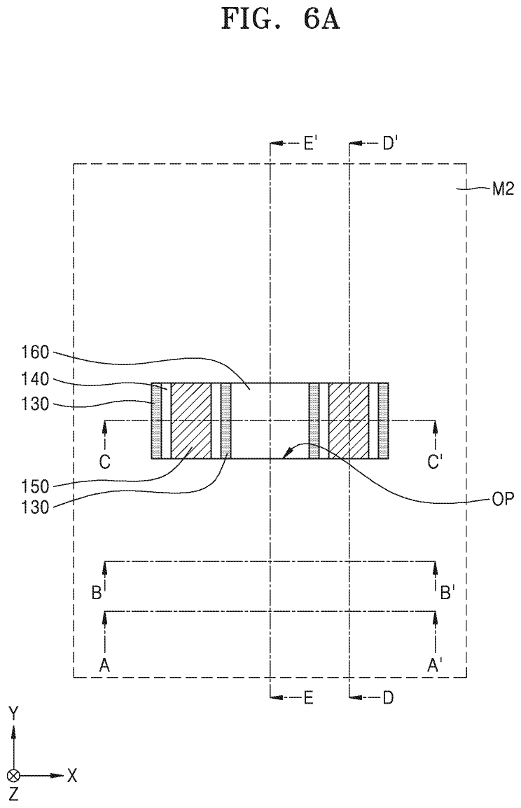

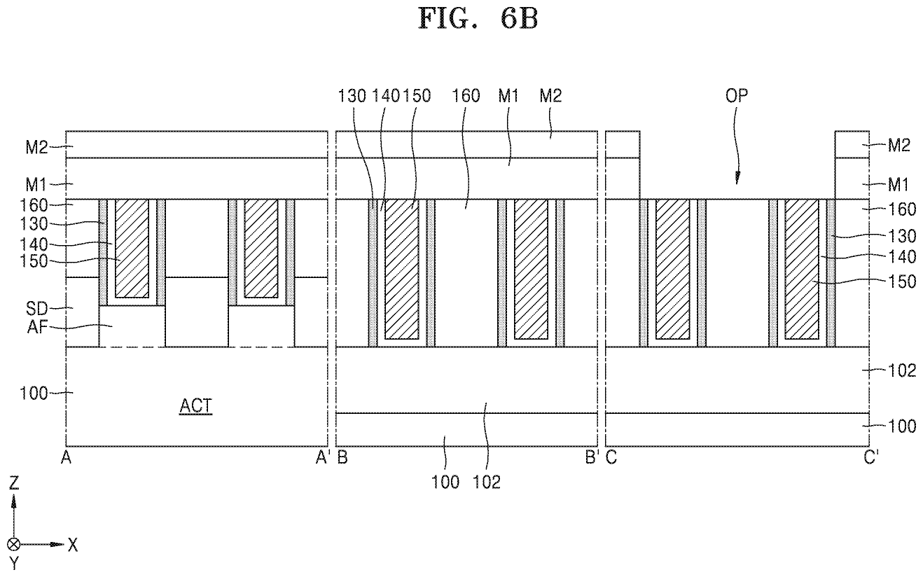

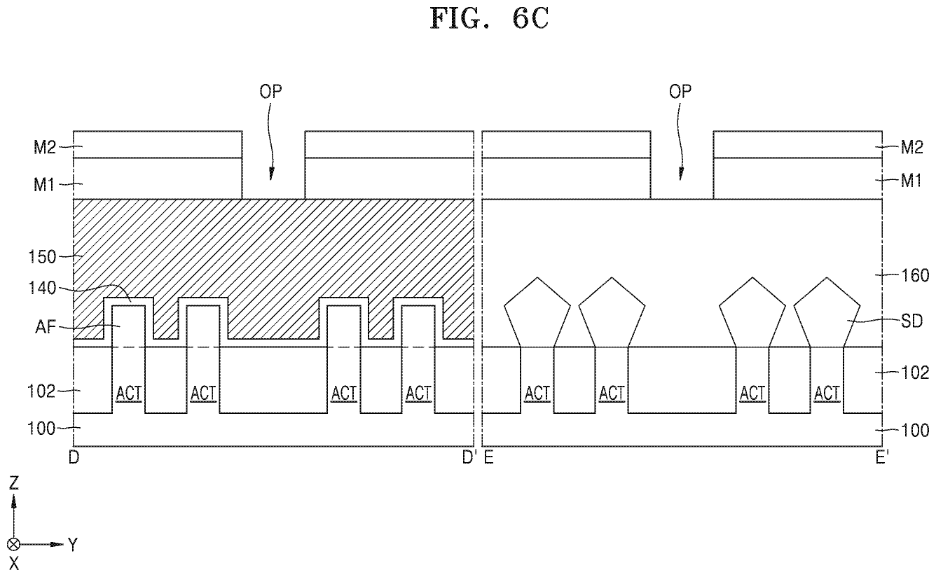

Referring to FIGS. 6A through 6C, first and second cutting mask patterns M1 and M2 having an opening OP that exposes a part of a top surface of the preliminary spacer 130, a part of a top surface of the preliminary gate dielectric layer 140, a part of a top surface of the preliminary gate electrode 150, and a part of a top surface of the interlayer insulating layer 160 may be sequentially formed.

When there are a plurality of preliminary gate electrodes 150, the plurality of preliminary gate electrodes 150 may each extend in the second direction Y and may be spaced apart from each other in the first direction X. In this case, the opening OP of the first and second cutting mask patterns M1 and M2 may extend in the first direction X to traverse the plurality of preliminary gate electrodes 150.

In detail, the opening OP may expose a part of the top surface of each of the plurality of preliminary gate electrodes 150 and a part of the top surface of the preliminary gate dielectric layer 140 provided on two sides of each of the plurality of preliminary gate electrodes 150. In addition, the opening OP may expose a part of the top surface of the preliminary spacer 130 provided on two sides of each of the plurality of preliminary gate dielectric layer 140 and a part of the top surface of the interlayer insulating layer 160 between the plurality of preliminary spacers 130.

The first and second cutting mask patterns M1 and M2 may include materials having different etch selectivities. The first cutting mask pattern M1 may include, for example, silicon nitride, and the second cutting mask pattern M2 may include, for example, spin-on-hardmask (SOH).

According to some embodiments, a process of forming the first and second cutting mask patterns M1 and M2 may include a process of forming a first cutting mask layer on the interlayer insulating layer, a process of forming a second cutting mask layer on the first cutting mask layer, and a process of forming a mask pattern (not shown) on the second cutting mask layer.

The mask pattern may have an opening pattern traversing the preliminary gate electrode 150 in a plan view. The opening pattern may define a region where the opening OP is to be formed on the second cutting mask layer. The first and second cutting mask patterns M1 and M2 may be formed by patterning the first and second cutting mask layers, respectively, by using the mask pattern as an etch mask. The mask pattern may be removed after the opening OP is formed.

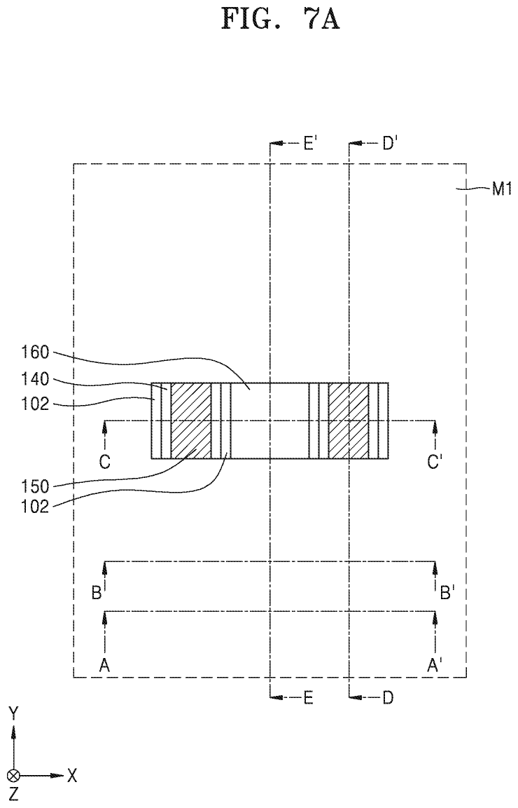

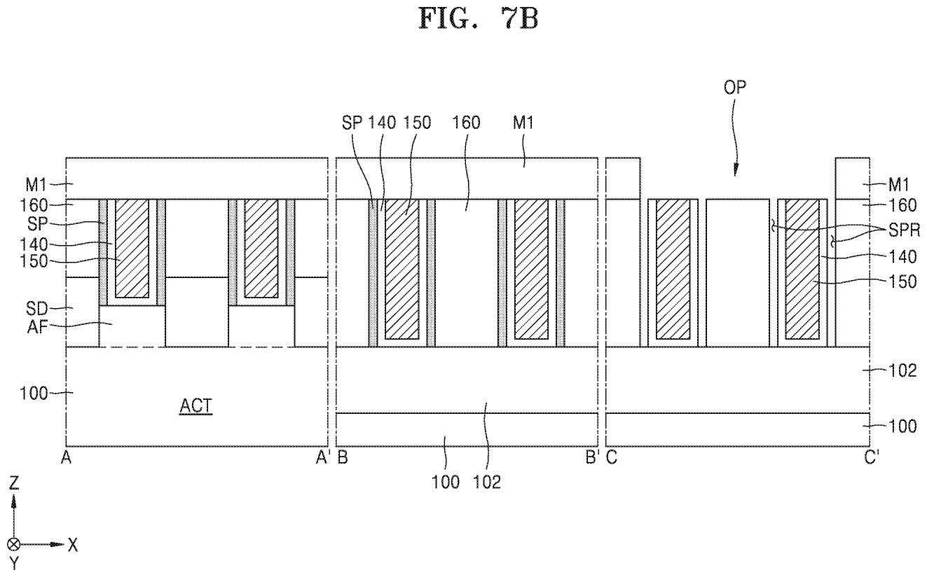

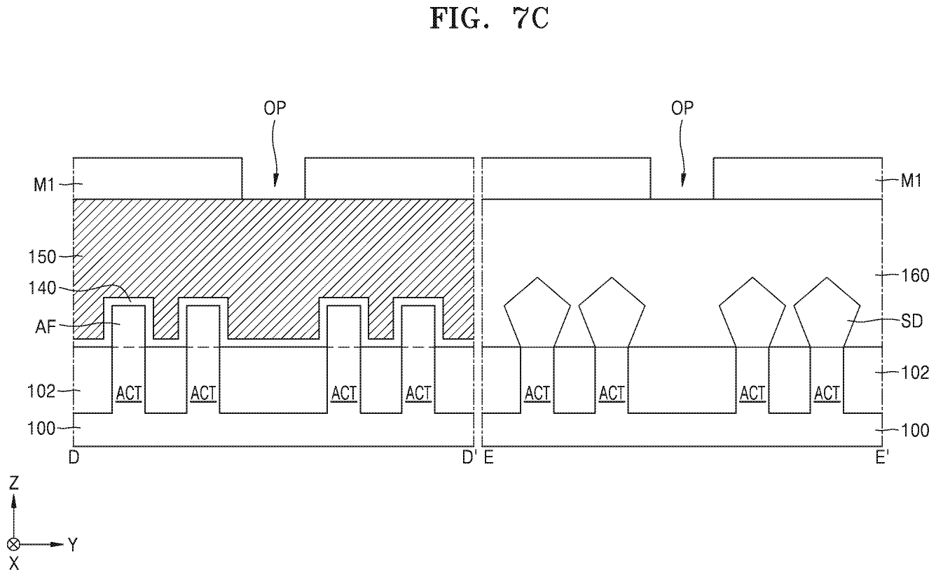

Referring to FIGS. 7A through 7C, a process of removing the preliminary spacer 130 exposed by the opening OP may be performed.

The process of removing the preliminary spacer 130 exposed by the opening OP may be a dry etch process using the second cutting mask pattern M2 as an etch mask. The dry etch process may have an etch condition having etch selectivity with respect to the preliminary gate dielectric layer 140, the preliminary gate electrode 150, and the interlayer insulating layer 160.

Through the process of removing the preliminary spacer 130, a side surface of the preliminary gate dielectric layer 140, a side surface of the interlayer insulating layer 160 facing the side surface of the preliminary gate dielectric layer 140, and a top surface of the device isolating layer 102 may be exposed. The preliminary gate dielectric layer 140, the preliminary gate electrode 150, and the interlayer insulating layer 160 may remain by not being removed during the process of removing the preliminary spacer 130 and may be exposed by the opening OP. The preliminary spacer 130 exposed by the opening OP may be removed, and the second cutting mask pattern M2 may be removed.

In other words, through the process of removing the preliminary spacer 130, a spacer cut region SPR may be formed by removing only a part of the preliminary spacer 130 exposed by the opening OP. Accordingly, the preliminary spacer 130 may be cut into a pair of spacers SP spaced apart from each other in the second direction Y.

In other words, the spacer SP may be formed through the process of removing the part of the preliminary spacer 130, and the spacers SP may extend in the second direction Y on a straight line with the spacer cut region SPR therebetween.

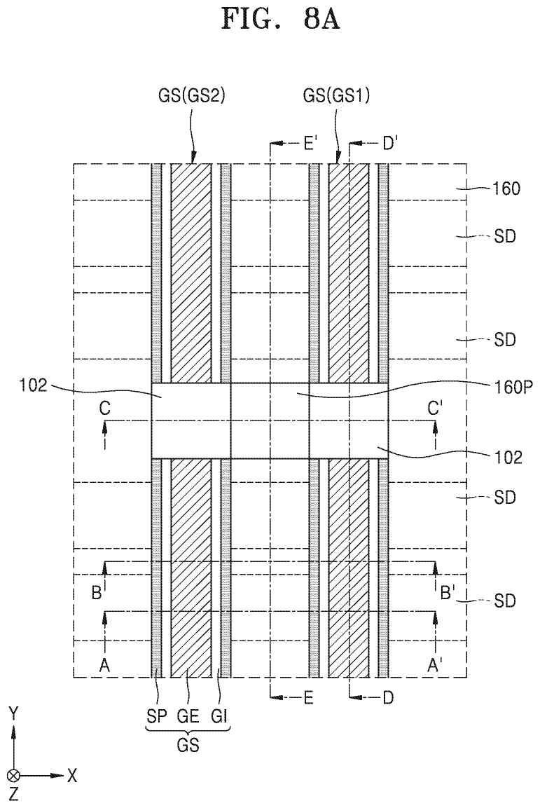

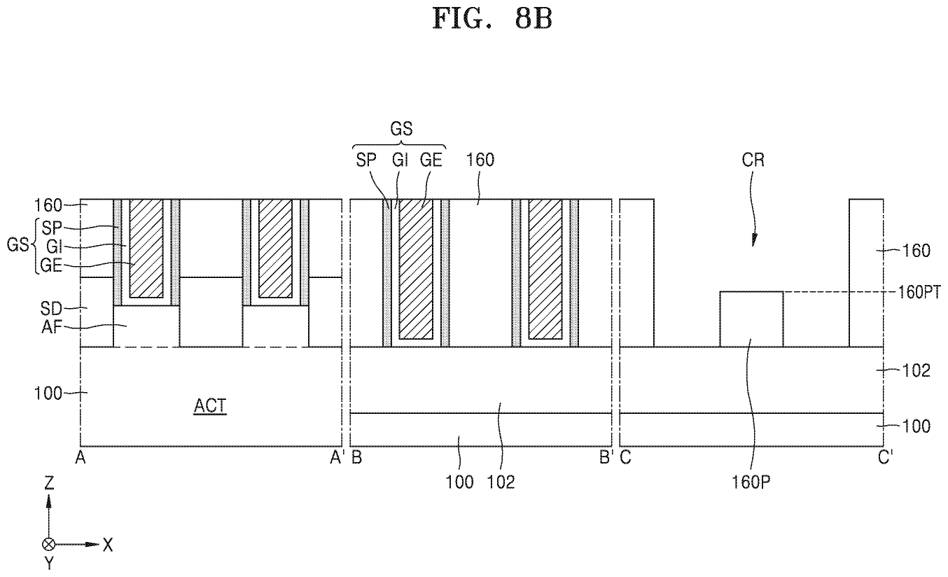

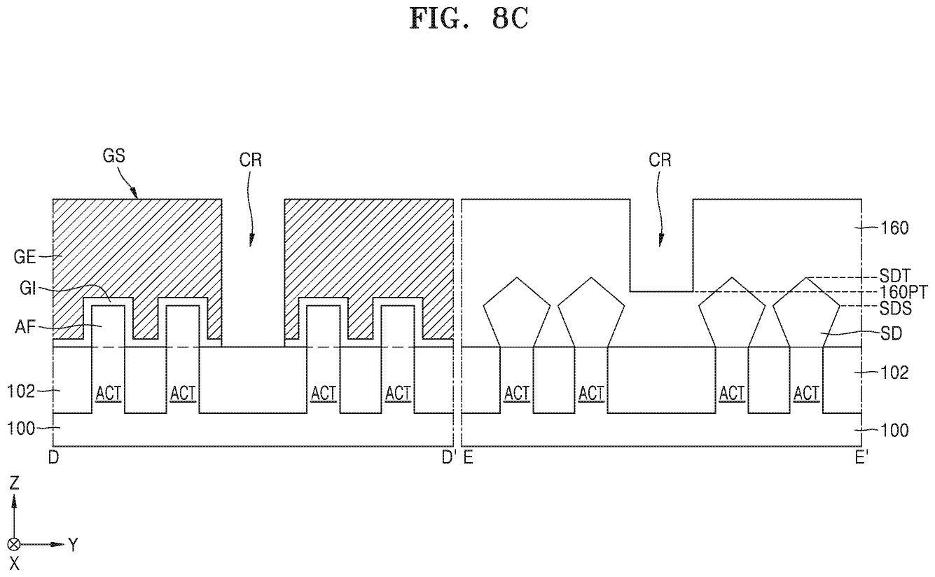

Referring to FIGS. 8A through 8C, after the process of removing the preliminary spacer 130, the preliminary gate electrode 150 exposed by the opening OP may be removed. Accordingly, the preliminary gate electrode 150 may be cut by the pair of gate electrodes GE spaced apart from each other in the second direction Y. In addition, the preliminary gate dielectric layer 140 exposed by the opening OP may also be removed. Accordingly, the preliminary gate dielectric layer 140 may be cut by the pair of gate dielectric layers GI spaced apart from each other in the second direction Y. Moreover, a part of the interlayer insulating layer 160 exposed by the opening OP may also be removed. However, only a part of the interlayer insulating layer 160 exposed by the opening OP may be removed such that the interlayer insulating pattern 160P remains. Such a removing process may have an etch condition having a partial etch selectivity with respect to the interlayer insulating layer 160.

Accordingly, the top surface of the device isolating layer 102 may be exposed between the pair of gate electrodes GE, between the pair of gate dielectric layers GI, and between the pair of spacers SP.

The removing process may be a dry etch process using the first cutting mask pattern M1 as an etch mask. Through the removing process, the preliminary gate electrode 150 may become the gate electrode GE, and the preliminary gate dielectric layer 140 may become the gate dielectric layer GI. The first cutting mask pattern M1 may be removed after the removing process.

Each of the pair of gate electrodes GE, the pair of gate dielectric layers GI provided on the bottom surface and the side surface of each of the pair of gate electrodes GE, and the spacer SP provided on the side surface of each of the pair of gate dielectric layers GI may be defined as the gate structure GS.

In other words, the pair of gate structures GS spaced apart from each other in the second direction Y may be formed on the substrate 100 when parts of the preliminary gate electrode 150, the preliminary gate dielectric layer 140, the preliminary spacer 130, and the interlayer insulating layer 160, which are exposed by the opening OP, are removed. A cut region CR may be defined between the pair of gate structures GS, and the cut region CR may expose the top surface of the device isolating layer 102 between the pair of gate structures GS.

The source/drain region SD that is a selective epitaxial growth layer may have the protruding point SDS at the side surface, in the second direction Y. A level of a top surface 160PT of the interlayer insulating pattern 160P may be lower than the level of the uppermost surface SDT of the source/drain region SD and higher than a level of the protruding point SDS. In other words, the cut region CR may reduce or prevent the source/drain region SD from being damaged.

Referring back to FIGS. 2A through 2C, the inter-gate cutting layer 170 filling the cut region CR may be formed. A process of forming the inter-gate cutting layer 170 may include a process of forming an insulating layer filling the cut region CR on the interlayer insulating layer 160 after the first cutting mask pattern M1 is removed and a process of flattening the insulating layer so that the interlayer insulating layer 160 is exposed. Accordingly, the level of the top surface of the inter-gate cutting layer 170 may be substantially the same as the level of the top surface of the interlayer insulating layer 160.

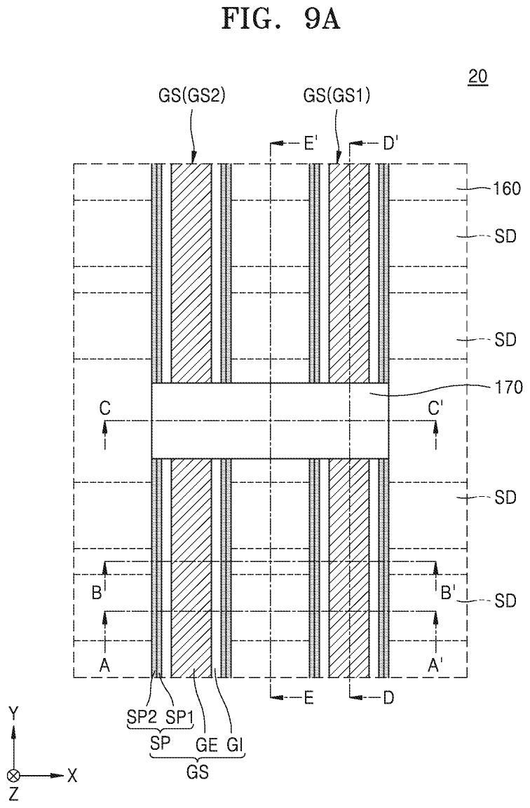

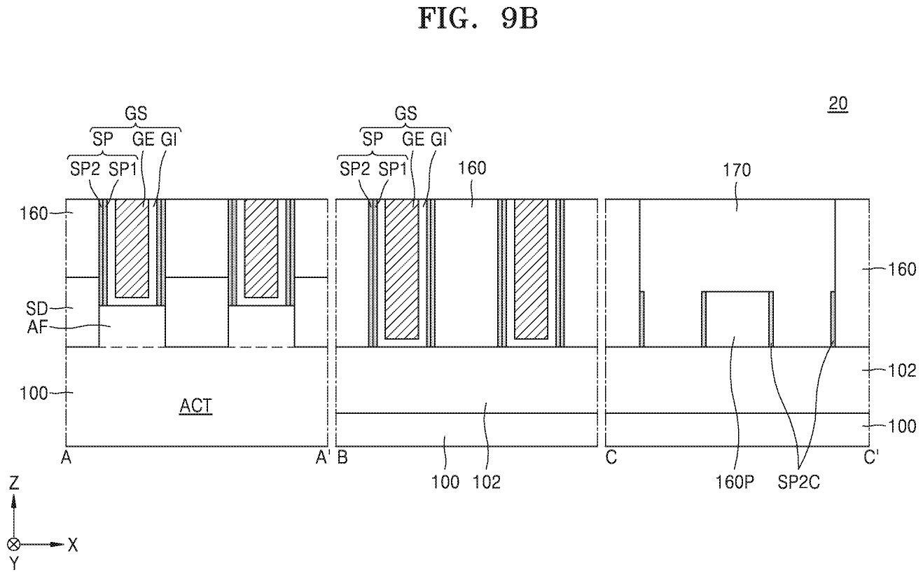

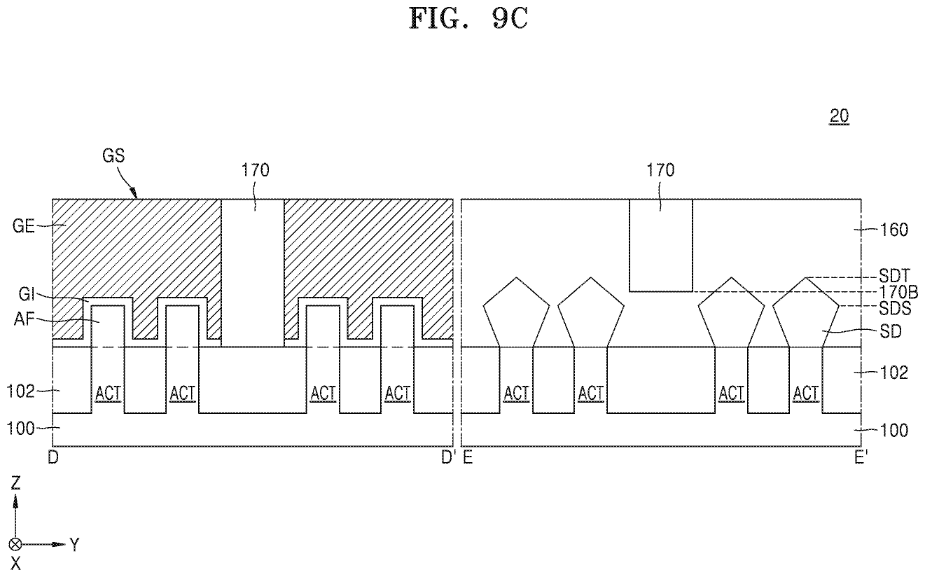

FIG. 9A is a plan view of a semiconductor device 20 according to another embodiment of the inventive concepts, FIG. 9B is a cross-sectional view taken along lines A-A′, B-B′, and C-C′ of FIG. 9A, and FIG. 9C is a cross-sectional view taken along lines D-D′ and E-E′ of FIG. 9A.

Since components included in the semiconductor device 20 and materials forming the components are the same as or similar to those described above with reference to FIGS. 2A through 2C, differences will be mainly described herein.

Referring to FIGS. 9A through 9C, the semiconductor device 20 includes the plurality of active regions ACT extending in the first direction X on the substrate 100, the plurality of gate structures GS spaced apart from each other in the first direction X and extending in the second direction Y crossing the plurality of active regions ACT, the source/drain region SD formed in a region not covered by the plurality of gate structures GS, the interlayer insulating layer 160 covering around the plurality of gate structures GS, and the inter-gate cutting layer 170 traversing the plurality of gate structures GS and the interlayer insulating layer 160 in the first direction X.

The gate structure GS includes the spacer SP including a multilayer material layer on two sides, and the number of material layers of the spacer SP provided at the inter-gate cutting layer 170 may be less than the number of material layers of the spacer SP provided at the gate structure GS.

The spacer SP may include a multilayer material layer structure including different insulating materials. According to some embodiments, the spacer SP may include a first spacer SP1 directly contacting a side surface of the gate dielectric layer GI, and second spacer SP2 spaced apart from the gate dielectric layer GI with the first spacer SP1 therebetween.

The second spacer SP2 may include a material having etch selectivity with respect to the first spacer SP1. The first spacer SP1 may include, for example, silicon nitride, and the second spacer SP2 may include, for example, silicon oxide or carbon-containing material layer.

A height of a remaining part SP2C of the second spacer SP provided at the inter-gate cutting layer 170 may be lower than a height of the spacer SP provided at the gate structure GS. In other words, the gate electrode GE and the gate dielectric layer GI are cut by the inter-gate cutting layer 170, whereas, since the remaining part SP2C of the second spacer SP2, which is a part of the spacer SP, is provided at the inter-gate cutting layer 170, the spacer SP may not be completely cut by the inter-gate cutting layer 170 but may extend in the second direction Y.

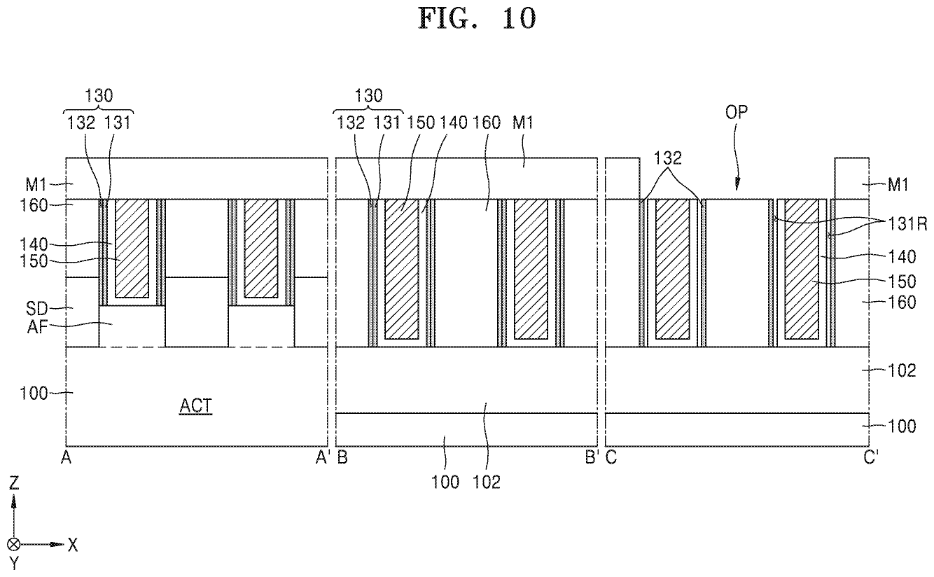

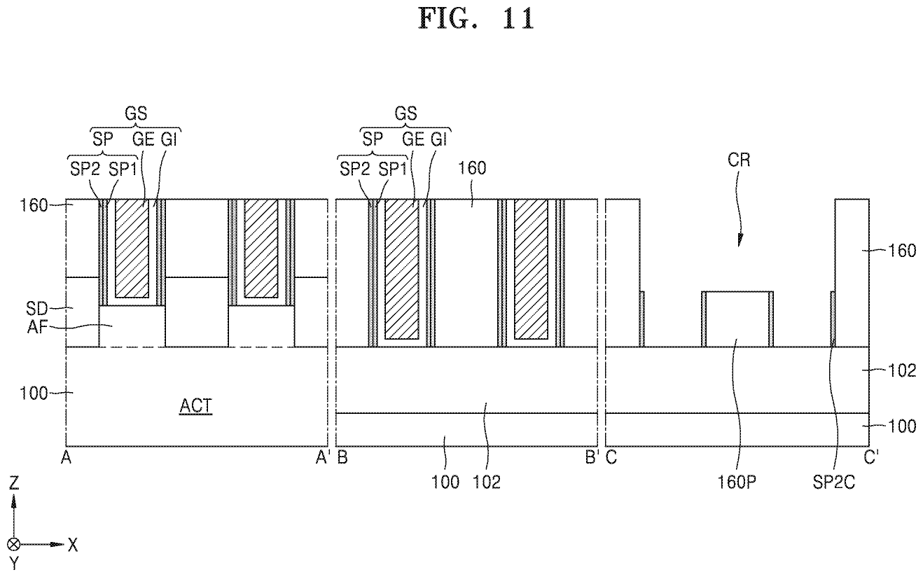

FIGS. 10 and 11 are cross-sectional views of the semiconductor device 20 in an order of processes of a part of a method of manufacturing the semiconductor device 20, according to another embodiment of the inventive concepts.

Since operations of the method of manufacturing the semiconductor device 20 are the same as or similar to those described above with reference to FIGS. 3A through 8C, differences will be mainly described herein.

Referring to FIG. 10, a process of removing a first preliminary spacer 131 that is a part of the preliminary spacer 130 exposed by the opening OP may be performed. For reference, the cross-sectional view of FIG. 10 is obtained after operations described above with reference to FIGS. 6A through 6C are performed.

The preliminary spacer 130 may have a multilayer material layer structure including different insulating materials. According to some embodiments, the preliminary spacer 130 may include the first preliminary spacer 131 directly contacting a side surface of the preliminary gate dielectric layer 140, and a second preliminary spacer 132 spaced apart from the preliminary gate dielectric layer 140 with the first preliminary spacer 131 therebetween.

Through the process of removing the first preliminary spacer 131 exposed by the opening OP, a side surface of the preliminary gate dielectric layer 140, a side surface of the second preliminary spacer 132 facing the side surface of the preliminary gate dielectric layer 140, and a top surface of the device isolating layer 102 may be exposed. The preliminary gate dielectric layer 140, the preliminary gate electrode 150, the interlayer insulating layer 160, and the second preliminary spacer 132 may not be removed but remain during the process of removing the first preliminary spacer 131.

In other words, through the process of removing the first preliminary spacer 131, only the first preliminary spacer 131 exposed by the opening OP may be removed such that a first preliminary spacer cut region 131R is formed. Accordingly, the first preliminary spacer 131 may be cut into the pair of first preliminary spacers 131 spaced apart from each other in the second direction Y.

Referring to FIG. 11, the preliminary gate electrode 150 exposed by the opening OP may be removed after the process of removing the first preliminary spacer 131. Accordingly, the preliminary gate electrode 150 may be cut into the pair of gate electrodes GE spaced apart from each other in the second direction Y. In addition, the preliminary gate dielectric layer 140 exposed by the opening OP may also be removed. Accordingly, the preliminary gate dielectric layer 140 may be cut into the pair of gate dielectric layers GI spaced apart from each other in the second direction Y. In addition, a part of the interlayer insulating layer 160 and a part of the second preliminary spacer 132, which are exposed by the opening OP, may also be removed. However, only a part of the interlayer insulating layer 160 may be removed such that the interlayer insulating pattern 160P remains, and only a part the second preliminary spacer 132 may be removed such that the remaining part SP2C remains. Such a removing process may have an etch condition having a partial etch selectivity with respect to the interlayer insulating layer 160 and the second preliminary spacer 132.

Accordingly, the cut region CR may expose the top surface of the device isolating layer 102 between the pair of gate electrodes GE, between the pair of gate dielectric layers GI, and between the pair of first spacers SP1.

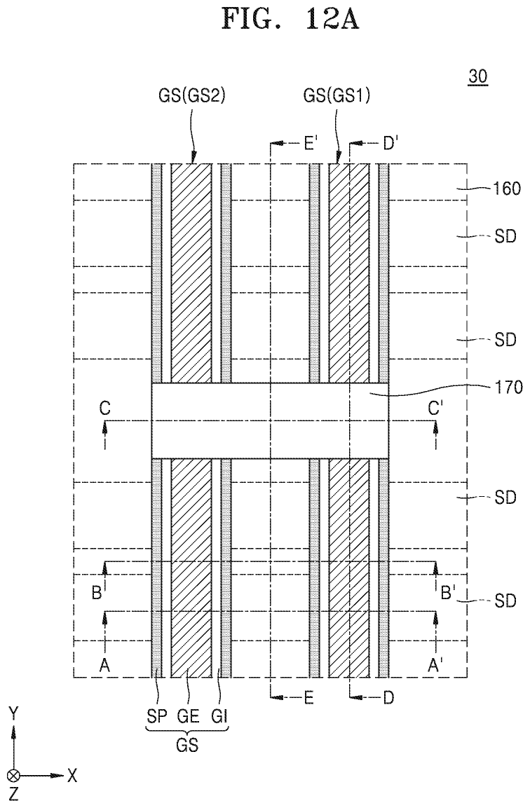

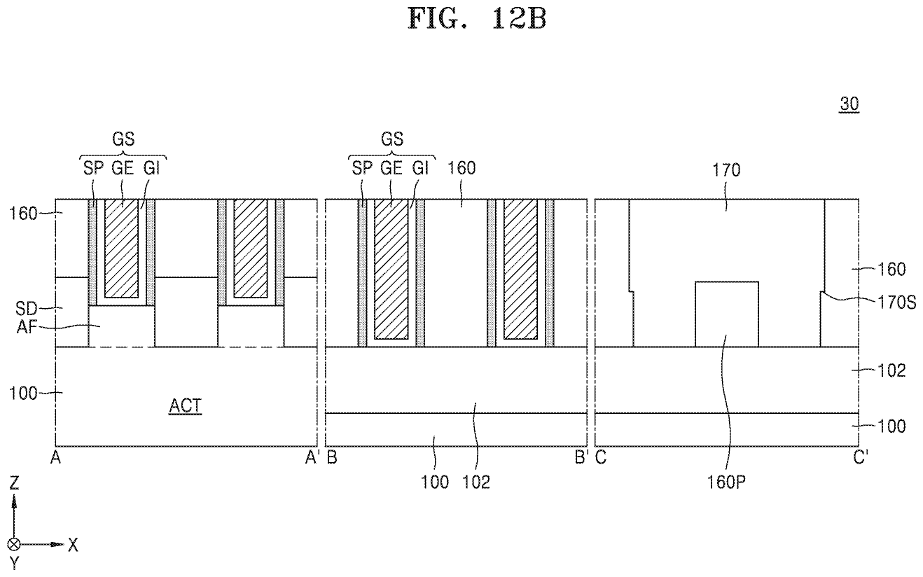

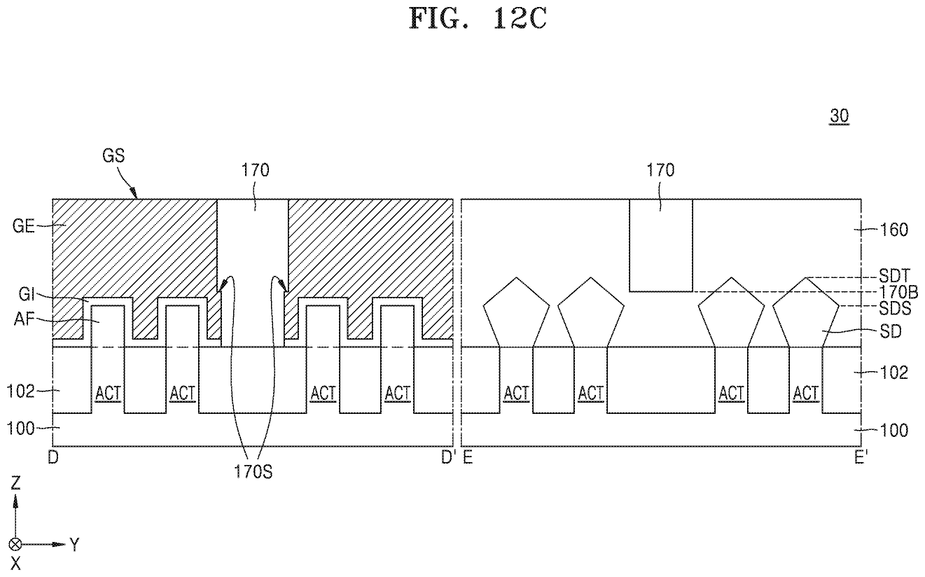

FIG. 12A is a plan view of a semiconductor device 30 according to another embodiment of the inventive concepts, FIG. 12B is a cross-sectional view taken along lines A-A′, B-B′, and C-C′ of FIG. 12A, and FIG. 12C is a cross-sectional view taken along lines D-D′ and E-E′ of FIG. 12A.

Since components included in the semiconductor device 30 and materials forming the components are the same as or similar to those described above with reference to FIGS. 2A through 2C, differences will be mainly described herein.

Referring to FIGS. 12A through 12C, the semiconductor device 30 includes the plurality of active regions ACT extending in the first direction X on the substrate 100, the plurality of gate structures GS spaced apart from each other in the first direction X and extending in the second direction Y crossing the plurality of active regions ACT, the source/drain region SD provided in a region not covered by the plurality of gate structures GS, the interlayer insulating layer 160 covering around the plurality of gate structures GS, and the inter-gate cutting layer 170 traversing the plurality of gate structures GS and the interlayer insulating layer 160 in the first direction X.

A profile of the inter-gate cutting layer 170 in the third direction Z at a region cutting the plurality of gate structures GS may have at least one stepped portion 170S. In other words, side surfaces of the inter-gate cutting layer 170, which contact the interlayer insulating layer 160 and contact the gate electrode GE, are not formed linearly in the third direction Z, but may be uneven having the stepped portion 170S.

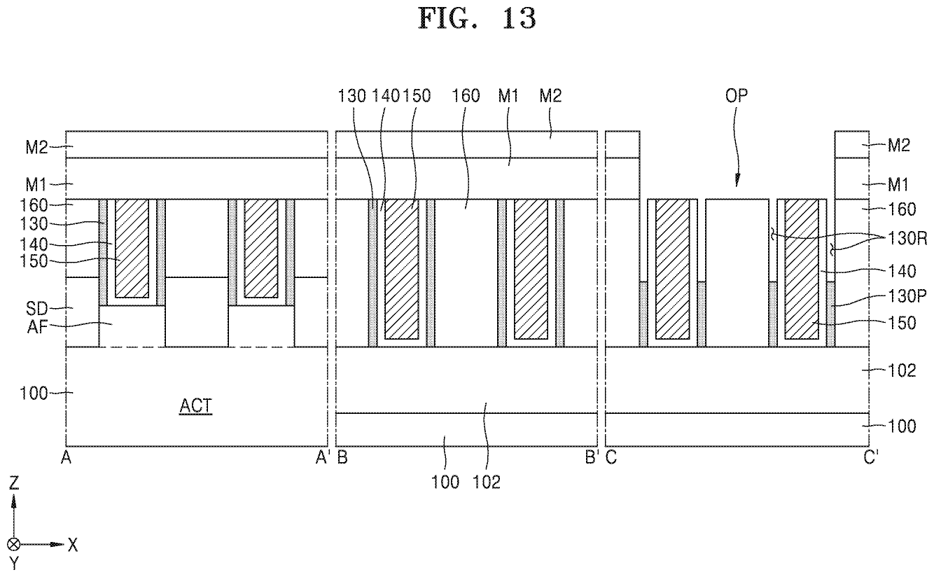

FIGS. 13 through 15 are cross-sectional views of the semiconductor device 30 in an order of processes of a part of a method of manufacturing a semiconductor device, according to another embodiment of the inventive concepts.

Since operations of the method of manufacturing the semiconductor device 30 are the same as or similar to those described above with reference to FIGS. 3A through 8C, differences will be mainly described herein.

Referring to FIG. 13, a process of removing a part of the preliminary spacer 130 exposed by the opening OP may be performed. For reference, the cross-sectional view of FIG. 13 is obtained after operations described above with reference to FIGS. 6A through 6C are performed.

The process of removing the part of the preliminary spacer 130 exposed by the opening OP may be a dry etch process using the second cutting mask pattern M2 as an etch mask. The dry etch process may have an etch condition having etch selectivity with respect to the preliminary gate dielectric layer 140, the preliminary gate electrode 150, and the interlayer insulating layer 160.

A preliminary spacer separating region 130R may be formed through the process of removing the part of the preliminary spacer 130. The preliminary gate dielectric layer 140, the preliminary gate electrode 150, and the interlayer insulating layer 160 may remain by not being removed during the process of removing the part of the preliminary spacer 130 and may be exposed by the opening OP.

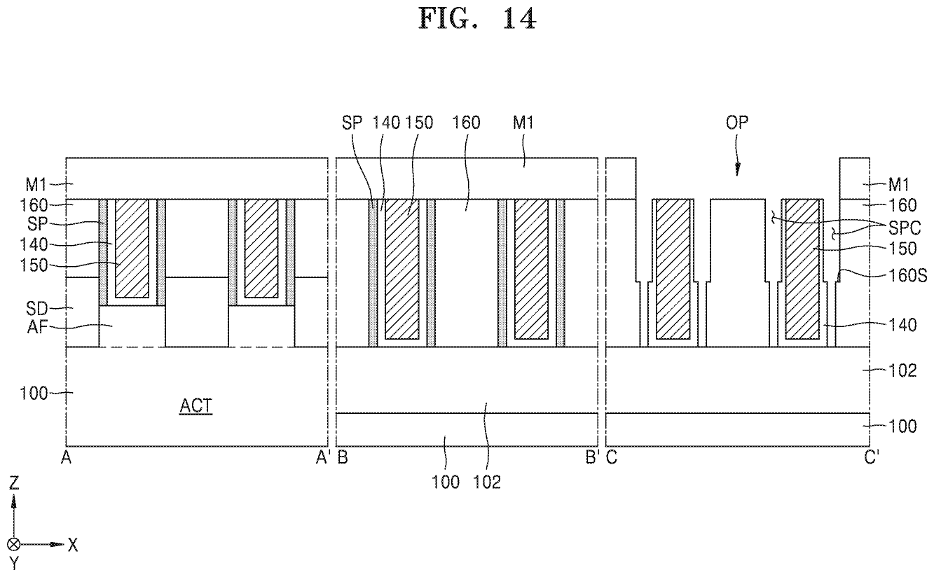

Referring to FIG. 14, a process of removing a remaining part 130P of the preliminary spacer 130 exposed by the opening OP may be performed.

In other words, a spacer cut region SPC may be formed by removing the preliminary spacer 130 exposed by the opening OP through the process of removing the remaining part 130P of the preliminary spacer 130. Accordingly, the preliminary spacer 130 may be cut into the pair of spacers SP spaced apart from each other in the second direction Y.

The process of removing the preliminary spacer 130 may be repeatedly performed at least twice to cut the preliminary spacer 130 into the pair of spacers SP. Since an aspect ratio of the preliminary spacer 130 is high, an etch space may be increased by removing the top of the preliminary spacer 130, and then the remaining part 130P of the preliminary spacer 130 may be removed.

After cutting the preliminary spacer 130 at least twice, a profile of the interlayer insulating layer 160 in the third direction Z at a region cut into the pair of spacers SP may have at least one stepped portion 160S.

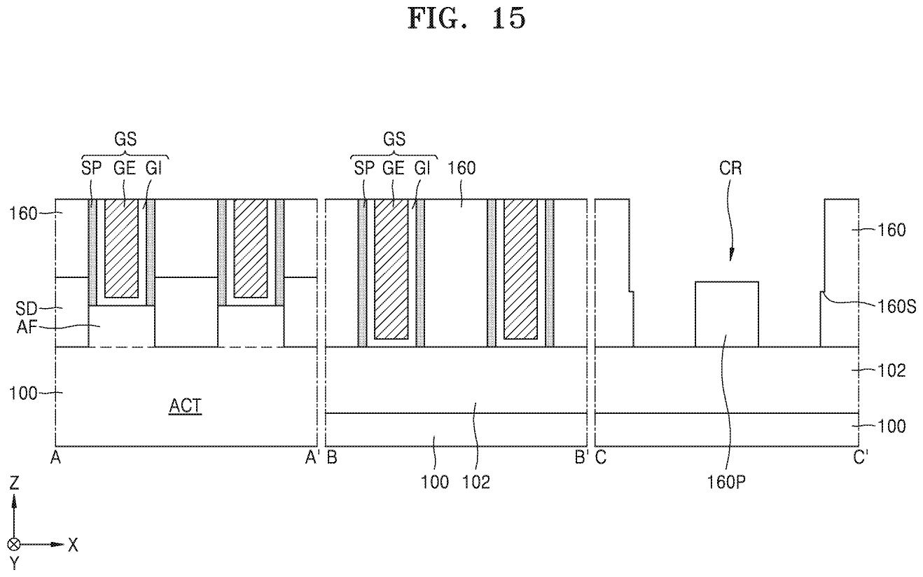

Referring to FIG. 15, after the process of removing the remaining part 130P of the preliminary spacer 130, the preliminary gate electrode 150 exposed by the opening OP may be removed. Accordingly, the preliminary gate electrode 150 may be cut into the pair of gate electrodes GE spaced apart from each other in the second direction Y. In addition, the preliminary gate dielectric layer 140 exposed by the opening OP may also be removed. Accordingly, the preliminary gate dielectric layer 140 may be cut into the pair of gate dielectric layers GI spaced apart from each other in the second direction Y. In addition, a part of the interlayer insulating layer 160 exposed by the opening OP may also be removed. However, the interlayer insulating layer 160 exposed by the opening OP may be removed such that the interlayer insulating pattern 160P remains.

Accordingly, the cut region CR may expose the top surface of the device isolating layer 102 between the pair of gate electrodes GE, between the pair of gate dielectric layers GI, and between the pair of spacers SP.

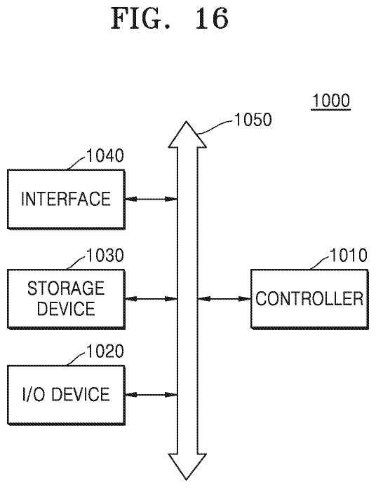

FIG. 16 is a diagram of a system 1000 including a semiconductor device, according to an embodiment of the inventive concepts.

Referring to FIG. 16, the system 1000 includes a controller 1010, an input/output (I/O) device 1020, a storage device 1030, an interface 1040, and/or a bus 1050.

The system 1000 may be a mobile system or a system that transmits or receives information. According to some embodiments, the mobile system may be a portable computer, a web tablet personal computer (PC), a mobile phone, a digital music player, or a memory card.

The controller 1010 controls an execution program in the system 1000 and may be a microprocessor, a digital signal processor, a microcontroller, or a similar device thereof.

The I/O device 1020 may be used to input or output data of the system 1000. The system 1000 may be connected to an external device, for example, a PC or a network, and exchange data with the external device by using the I/O device 1020. The I/O device 1020 may be, for example, a touch pad, a keyboard, or a display.

The storage device 1030 may store data for operations of the controller 1010, or store data processed by the controller 1010. The storage device 1030 may include the semiconductor device 10, 20, or 30 according to one or more embodiments of the inventive concepts.

The interface 1040 may be a data transmission path between the system 1000 and the external device. The controller 1010, the I/O device 1020, the storage device 1030, and the interface 1040 may communicate with each other through the bus 1050.

While the inventive concepts have been particularly shown and described with reference to embodiments thereof, it will be understood that various changes in form and details may be made therein without departing from the spirit and scope of the following claims.

1. A semiconductor device comprising:
a plurality of active regions on a substrate extending in a first direction;
first and second gate structures spaced apart from each other in the first direction and extending on the substrate in a second direction crossing the plurality of active regions;
an interlayer insulating layer around the first and second gate structures; and
an inter-gate cutting layer traversing the first and second gate structures and the interlayer insulating layer in the first direction, the inter-gate cutting layer comprising an insulating material,
wherein the first and second gate structures are separated by the inter-gate cutting layer,
wherein a level of a bottom surface of the inter-gate cutting layer at a region cutting the first and second gate structures is lower than a level of a bottom surface of the inter-gate cutting layer in the interlayer insulating layer.

2. The semiconductor device of claim 1, wherein the first and second gate structures each comprise a gate electrode comprising a metal material.

3. The semiconductor device of claim 1, wherein the plurality of active regions each comprise a plurality of active fins protruding from the substrate,
wherein the first and second gate structures extend to cover a first active region comprising at least one active fin among the plurality of active fins and a second active region separated from the first active region and comprising another at least one active fin, respectively.

4. The semiconductor device of claim 3, wherein the inter-gate cutting layer is between the first and second active regions,
wherein a bottom surface of the inter-gate cutting layer is an uneven surface and a top surface of the inter-gate cutting layer is a relatively flat surface.

5. The semiconductor device of claim 1, wherein a source/drain region having a protruding point in the second direction is at a region of the plurality of active regions, which is not covered by the first and second gate structures,
wherein a level of a bottom surface of the inter-gate cutting layer in the interlayer insulating layer is lower than a level of an uppermost surface of the source/drain region and higher than a level of the protruding point.

6. The semiconductor device of claim 1, wherein a width of the inter-gate cutting layer in the first direction at a region cutting the first and second gate structures has at least one stepped portion in a vertical direction on a top surface of the substrate.

7. The semiconductor device of claim 1, wherein the first and second gate structures each comprise a spacer,
wherein the spacer comprises a multilayer material layer comprising different materials,
wherein only a partial material layer within the multilayer material layer is cut by the inter-gate cutting layer.

8. The semiconductor device of claim 1, further comprising a device isolating layer defining the plurality of active regions on the substrate,
wherein a bottom surface of the inter-gate cutting layer at a region separating the first and second gate structures directly contacts a top surface of the device isolating layer,
wherein a bottom surface of the inter-gate cutting layer in the interlayer insulating layer directly contacts the interlayer insulating layer.

9. The semiconductor device of claim 1, wherein the first and second gate structures each comprise a gate electrode and a gate dielectric layer,
wherein the gate electrode and the gate dielectric layer are separated by the inter-gate cutting layer.

10. The semiconductor device of claim 9, wherein a level of a top surface of the gate electrode is substantially the same as a level of a top surface of the inter-gate cutting layer.

11. A semiconductor device comprising:
a plurality of active fins on a substrate extending in a first direction;
first and second gate structures spaced apart from each other in the first direction and extending on the substrate in a second direction crossing the plurality of active fins;
a source/drain region in a region of the plurality of active fins, which is not covered by the first and second gate structures;
an interlayer insulating layer covering the source/drain region around the first and second gate structures; and
an inter-gate cutting layer traversing the first and second gate structures and the interlayer insulating layer in the first direction,
wherein the first and second gate structures each comprise a spacer comprising a multilayer material layer on two side surfaces thereof,
wherein the number of material layers of the spacer provided at the inter-gate cutting layer is less than the number of material layers of the spacer provided at the first and second gate structures,
wherein a level of a bottom surface of the inter-gate cutting layer at a region cutting the first and second gate structures is lower than a level of a bottom surface of the inter-gate cutting layer in the interlayer insulating layer.

12. The semiconductor device of claim 11, wherein the first and second gate structures each comprise a gate electrode comprising a metal material, and
the inter-gate cutting layer comprises an insulating material.

13. The semiconductor device of claim 11, wherein a height of the spacer at the inter-gate cutting layer is lower than a height of the spacer at the first and second gate structures.

14. The semiconductor device of claim 13, wherein the first and second gate structures each comprise a gate electrode and a gate dielectric layer.
wherein the spacer has a thickness decreasing in the first direction by the inter-gate cutting layer,
wherein the gate electrode and the gate dielectric layer are separated by the inter-gate cutting layer.

15. The semiconductor device of claim 11, wherein the source/drain region comprises a selective epitaxial growth layer having a protruding point in the second direction,
wherein a level of a bottom surface of the inter-gate cutting layer in the interlayer insulating layer is lower than a level of an uppermost surface of the source/drain region and higher than a level of the protruding point.

16. A method of manufacturing a semiconductor device, the method comprising:
forming a plurality of active regions extending on a substrate in a first direction, and a device isolating layer defining the plurality of active regions;
forming a dummy gate structure comprising a dummy gate pattern and a spacer, and extending on the device isolating layer in a second direction while crossing the plurality of active regions;
forming a source/drain region at a region of the plurality of active regions, which is exposed at two sides of the dummy gate structure;
forming an interlayer insulating layer covering the device isolating layer and the source/drain region around the dummy gate structure;
forming an empty space extending in the second direction between the spacer by removing the dummy gate pattern;
forming a gate structure comprising a gate electrode and the spacer by filling the empty space with a metal material to form the gate electrode;
removing a part of the spacer; and
cutting the gate electrode by removing a region where a side surface of the gate electrode is exposed when the spacer is removed within the gate electrode.

17. The method of claim 16, wherein the cutting of the gate electrode comprises:
forming a cut region in the gate structure by removing a part of the gate electrode; and
forming an inter-gate cutting layer in the cut region.

18. The method of claim 17, after the forming of the cut region, exposing the device isolating layer in the cut region.

19. The method of claim 17, wherein the forming of the inter-gate Cutting layer comprises forming the inter-gate cutting layer such that a bottom surface of the inter-gate cutting layer directly contacts a top surface of the device isolating layer.

20. The method of claim 16, wherein the gate structure comprises first and second gate structures spaced apart from each other in the first direction,
wherein the cutting of the gate electrode comprises:
forming a cut region traversing the first and second gate structures by removing a part of the first and second gate structures; and
forming an inter-gate cutting layer in the cut region, the inter-gate cutting layer comprising an insulating material.

21.-25. (canceled)
